(19) United States
(12) Patent Application Publication
(10) Pub. No.: US 2024/0250109 A1
(43) Pub. Date: Jul. 25, 2024

(54) METHOD FOR REDUCING WHITE SPOTS IN IMAGE SENSOR

(71) Applicant: Samsung Electronics Co., Ltd., Suwon-si (KR)

(72) Inventors: Juntaek Lee, Suwon-si (KR); Yunjeong Park, Suwon-si (KR); Sanghyeon Lee, Suwon-si (KR); Seulrim Lee, Suwon-si (KR); Jungsup Hong, Suwon-si (KR)

(21) Appl. No.: 18/460,802

(22) Filed: Sep. 5, 2023

(30) Foreign Application Priority Data
Jan. 25, 2023 (KR) 10-2023-0009634

(51) Int. Cl. H01L 27/146; H01L 21/66

(52) U.S. Cl. CPC H01L 27/14698; H01L 22/20

(57) ABSTRACT

A method for reducing white spots of the image sensor may include: manufacturing an image sensor; testing the manufactured image sensor to select an image sensor without defects; and heat-treating the selected image sensor without defects.

### CROSS-REFERENCE TO RELATED APPLICATION

This application claims priority to and the benefit of Korean Patent Application No. 10-2023-0009634, filed in the Korean Intellectual Property Office on Jan. 25, 2023, the entire contents of which are incorporated herein by reference.

### BACKGROUND

The present disclosure relates to methods for reducing white spots of an image sensor.

An image sensor is a semiconductor device that converts an optical image into an electrical signal, and includes a Charge Coupled Device (CCD) image sensor and a Complementary Metal-Oxide Semiconductor (CMOS) image sensor.

Among them, the CMOS image sensor has a merit of low power consumption and a low manufacturing cost due to a small size of the device compared to the CCD image sensor with a high voltage analog circuit. Accordingly, the CMOS image sensors are mainly installed in home appliances as well as portable devices such as smartphones and digital cameras.

### SUMMARY

The present disclosure provides methods for reducing white spots of an image sensor, which may improve quality and yield of the image sensor by suppressing an occurrence of white spots.

A method for reducing white spots of an image sensor according to an embodiment includes: manufacturing an image sensor; testing the manufactured image sensor to select an image sensor without defects; and heat-treating the selected image sensor without defects.

A method for reducing white spots of an image sensor according to another embodiment includes: manufacturing an image sensor; testing the manufactured image sensor to select an image sensor without defects; first heat-treating the selected image sensor without defects in a range of 70 degrees Celsius to 120 degrees Celsius for 30 minutes to 5 hours; and second heat-treating the first heat-treated image sensor at a temperature at least or greater than 50 degrees higher than that of the first heat-treating.

A method for reducing white spots of an image sensor according to another embodiment includes, in a manufacturing method of an image sensor: forming a color filter on a substrate; forming a microlens on the color filter; and heat-treating the image sensor on which the microlens is formed, wherein the heat-treating may be performed in multiple stages.

According to the embodiments, by performing the heat treatment process on the image sensor, it is possible to dramatically reduce a white spot defect rate of which an incidence increases over time.

Specifically, by performing the heat treatment process of a low temperature or multi-stage on the image sensor selected as a good product, an occurrence of white spot defects may be effectively reduced, and accordingly, the yield of the image sensor may be significantly improved.

The various yet beneficial merits and effects of the present disclosure are not limited to the above, and will be more easily understood in the process of explaining specific embodiments of the present disclosure.

### BRIEF DESCRIPTION OF THE DRAWINGS

FIG. 1 is a flowchart illustrating a method for reducing white spots of an image sensor according to an embodiment.

FIG. 2 is a view schematically showing a structure of an image sensor manufactured according to a manufacturing method of an image sensor included in the present disclosure.

FIG. 3 to FIG. 7 are views showing various illustrative embodiments for a case in which a step of heat-treating an image sensor selected as having no defects is performed in multiple stages in a method for reducing white spots of an image sensor according to embodiments.

FIG. 8 and FIG. 9 are views showing various embodiments for a case of performing a step of heat-treating an image sensor selected as having no defects in a method for reducing white spots of an image sensor.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways without departing from the spirit or scope of the present disclosure.

In order to clarify the present disclosure, parts that are not connected with the description will be omitted, and the same elements or equivalents are referred to by the same reference numerals throughout the specification.

Further, since sizes and thicknesses of constituent members shown in the accompanying drawings may be arbitrarily given for better understanding and ease of description, the present disclosure is not limited to the illustrated sizes and thicknesses. In the drawings, the thickness of layers, films, panels, regions, etc., may be exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” may mean positioned on or below the object portion, and does not necessarily mean positioned on the upper side of the object portion based on a gravitational direction unless the context clearly indicates otherwise.

In addition, unless explicitly described to the contrary, the word “comprise”, and variations such as “comprises” or “comprising”, will be understood to imply the inclusion of stated elements but not the exclusion of any other elements.

Further, in the specification, the phrase “on a plane” means when an object portion is viewed from above, and the phrase “on a cross-section” means when a cross-section taken by vertically cutting an object portion is viewed from the side.

Hereinafter, methods for reducing white spots of an image sensor according to example embodiments will be described.

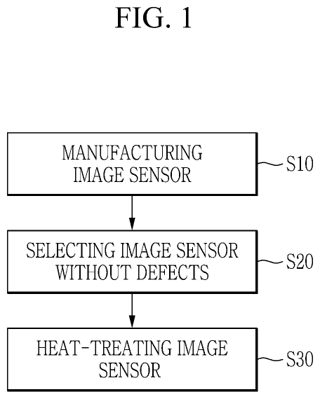

FIG. 1 is a flowchart illustrating a method for reducing white spots of an image sensor according to an embodiment.

Referring to FIG. 1, a method for reducing white spots of an image sensor according to an embodiment may include manufacturing an image sensor (S10), selecting an image sensor without defects (S20), and heat-treating the image sensor (S30).

First, the manufacturing (S10) of the image sensor may include forming a color filter 170 on a substrate 110 and forming a microlens 180 on the color filter 170.

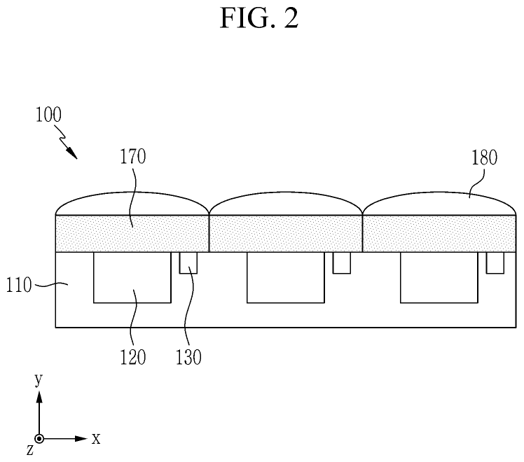

FIG. 2 is a view schematically showing a structure of an image sensor manufactured according to a manufacturing method of an image sensor included in the present disclosure. The image sensor 100 manufactured according to the present embodiment may be an example of a CMOS image sensor.

The substrate 110 may be a semiconductor substrate. For example, the substrate 110 may be bulk silicon or a silicon-on-insulator (SOI). The substrate 110 may be a silicon substrate, or other materials, for example, may include silicon germanium, indium antimonide, lead tellurium, indium arsenic, indium phosphide, gallium arsenic, or gallium antimonide. Alternatively, the substrate 110 may have an epitaxial layer formed on the base substrate.

A transfer transistor and a charge storage 130 may be integrated in a photo-sensing element 120 on the substrate 110.

The photo-sensing element 120 may be a photodiode.

The photo-sensing element 120 may include a p-n junction or a pin junction.

The photo-sensing element 120 may include an inorganic semiconductor selected from Si, Ge, GaAs, InP, GaN, AlN, CdTe, ZnTe, copper indium gallium (di)selenide (CIGS) and combinations thereof.

The photo-sensing element 120, the transfer transistor, and/or the charge storage 130 may be integrated for each pixel. For example, the photo-sensing element 120 may be included in a green pixel, a blue pixel, and a red pixel, respectively. The photo-sensing element 120 senses light, and the sensed information may be transmitted to the charge storage 130 by the transfer transistor.

A CMOS circuit part may be disposed under the substrate 110. The CMOS circuit part may include the transfer transistor and/or the charge storage.

A color filter 170 may be formed on the substrate 110 and may have various color filters according to the unit pixel region. For example, the color filter 170 may be arranged in a Bayer pattern including a red color filter, a green color filter, and a blue color filter. However, this is just an example, and the color filter 170 may include a yellow filter, a magenta filter, and a cyan filter, or may further include a white filter.

A microlens 180 may be formed on the color filter 170. The microlens 180 may be arranged to correspond to each unit pixel region. For example, the microlens 180 may be arranged two-dimensionally (e.g., in a matrix form) on a plane.

The microlens 180 has a convex shape and may have a predetermined curvature radius. Accordingly, the microlens 180 may condense light incident on the photo-sensing element 120. The microlens 180 may include, for example, a light-transmitting resin, but is not limited thereto.

Next, testing the image sensor 100 manufactured as described above and selecting the image sensor without defects is performed (S20).

The selecting (S20) of the image sensor without defects may be performed by, for example, contacting a probe card with a wafer on which the image sensor is mounted. Numerous fine pins on the probe card may be in contact with the wafer to send electricity and to sort out defective chips through the signal, so that good chips without defects may be sorted.

More specifically, the sorting of the defective chips, for example, may include: applying heat of a certain temperature to an individual device such as transistors, resistors, capacitors, and diodes, and then applying an AC and DC voltage to determine whether the product operates normally; determining whether the product operates normally at a temperature higher and lower than room temperature; repairing the chips determined to be repairable and verifying whether the repair is properly performed to finally determine whether there is a defect or not; and imprinting a special ink on the defective chip to identify the defect with a naked eye.

Next, the present embodiment includes heat treating the image sensor determined to be non-defective, i.e., good, through the above process (S30).

The principle of converting light into charges (photoelectric conversion) in the image sensor forms a pn junction and has a depletion layer as a structure. However, in the case of the image sensor classified into having no defects through the selection (sorting) process as described above, as time passes, even though no light is incident, electron-hole pairs are generated in the depletion layer due to cosmic rays, alpha particles, and radiation, and charges are generated, resulting in a problem with defects of a white spot. These white spot defects increase linearly with time. That is, as time elapses, a defect occurrence rate increases. This is very fatal for the CMOS image sensor products that require high yield and may lead to the quality degradation of the image sensor.

However, in the present embodiment, the occurrence rate of the white spots may be significantly reduced by performing a heat treatment process on the image sensors selected as having no defects.

Specifically, the heat treating (S30) of the image sensor selected as having no defects may be performed in multiple stages.

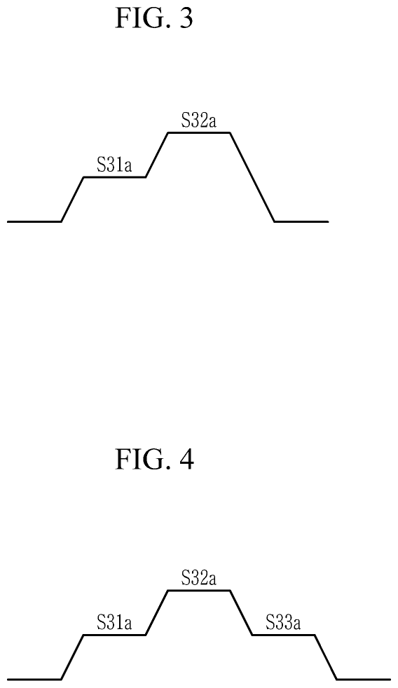

FIG. 3 to FIG. 7 are views showing various illustrative embodiments for a case in which a step of heat-treating an image sensor selected as having no defects is performed in multiple stages in a method for reducing white spots of an image sensor according to embodiments.

Referring to FIG. 3 to FIG. 7, in the method for reducing the white spots of the image sensor of the embodiments, the heat treatment of the image sensor performed in the multiple stages may include a first heat treatment performed at 150 degrees Celsius or less, and a second heat treatment performed at a temperature higher than the first heat treatment.

In detail, referring to FIG. 3, the method for reducing the white spots of the image sensor according to an Embodiment 1, the heat treatment of the image sensor may include a first heat treatment step (S31a) performed at 150 degrees Celsius or less, and a second heat treatment step (S32a) performed at a higher temperature than the first heat treatment.

At this time, a temperature difference between the processes of performing the first heat treatment and the second heat treatment may be 50 degrees Celsius or more, specifically 50 Celsius degrees to 100 Celsius degrees, or 70 degrees Celsius to 80 degrees Celsius.

Specifically, the first heat treatment (S31a) may be performed for 30 minutes to 5 hours in the range of 90 degrees Celsius to 150 degrees Celsius or 110 degrees Celsius to 130 degrees Celsius, for example.

In addition, the second heat treatment (S32a) may be performed for 30 minutes to 5 hours in the range of 160 degrees Celsius to 210 degrees Celsius or 180 degrees Celsius to 200 degrees Celsius, for example.

Referring to FIG. 4, in the method for reducing the white spots of the image sensor according to an Embodiment 2, the heat treatment of the image sensor may include a first heat treatment (S31a) performed at 150 degrees Celsius or less, a second heat treatment (S32a) performed at a higher temperature than the first heat treatment, and a third heat treatment (S33a) performed at a lower temperature than the second heat treatment.

In the present embodiment, the temperature and time conditions of the first heat treatment (S31a) and the second heat treatment (S32a) may be the same as the Embodiment 1.

In addition, the third heat treatment (S33a) may be performed under the same temperature and time conditions as the process of performing the first heat treatment (S31a).

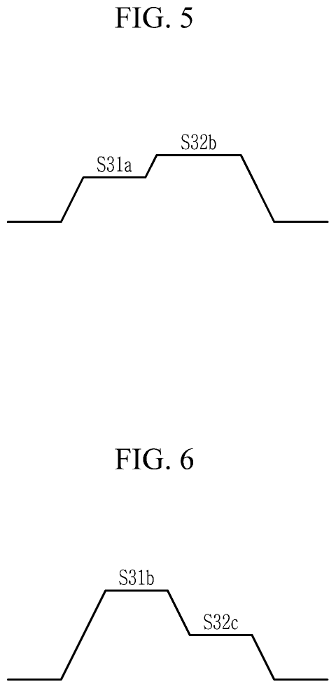

Referring to FIG. 5, in the method for reducing the white spots of the image sensor according to an Embodiment 3 the heat treatment of the image sensor may include a first heat treatment (S31a) performed at 150 degrees Celsius or less and a second heat treatment (S32b) performed at a higher temperature than the first heat treatment, and the temperature difference of the processes performing the first treatment (S31a) and the second heat treatment (S32b) may be less than 50 degrees.

At this time, the temperature difference between the processes of performing the first heat treatment and the second heat treatment may be 50 degrees Celsius or less, specifically 20 degrees Celsius to 50 degrees Celsius, or 25 degrees Celsius to 35 degrees Celsius.

Specifically, the first heat treatment (S31a) may be performed for 30 minutes to 5 hours in the range of 90 degrees Celsius to 150 degrees Celsius or 110 degrees Celsius to 130 degrees Celsius, for example.

In addition, the second heat treatment (S32b) of Embodiment 3 may be performed for 30 minutes to 5 hours in the range of 120 degrees Celsius to 170 degrees Celsius or 140 degrees Celsius to 160 degrees Celsius, for example.

Referring to FIG. 6, in the method for reducing the white spots of the image sensor according to an Embodiment 4, the heat treatment of the image sensor may include a first heat treatment (S31b) performed at 170 degrees Celsius or more, and a second heat treatment (S32c) performed at a lower temperature than the first heat treatment.

In Embodiment 4, the first heat treatment (S31b) may be performed for 30 minutes to 5 hours in the range of 170 degrees Celsius to 220 degrees Celsius, or 180 degrees Celsius to 200 degrees Celsius, for example.

In addition, the second heat treatment (S32c) may be performed for 30 minutes to 5 hours in the range of 90 degrees Celsius to 150 degrees Celsius, or 110 degrees Celsius to 130 degrees Celsius, for example.

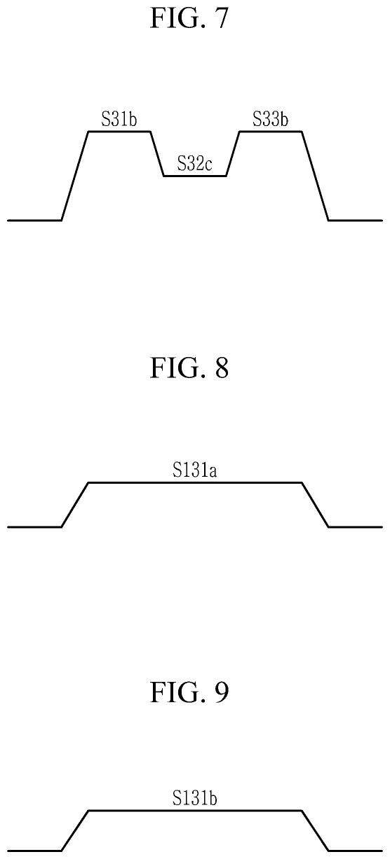

Referring to FIG. 7, in the method for reducing the white spots of the image sensor according to an Embodiment 5, the heat treatment of the image sensor may include a first heat treatment (S31b) performed at 170 degrees Celsius or more, a second heat treatment (S32c) performed at a temperature lower than the first heat treatment, and a third heat treatment (S33b) performed at a temperature higher than the second heat treatment.

In the present embodiment, the temperature and time conditions of the first heat treatment and the second heat treatment may be the same as the Embodiment 4.

In addition, the third heat treatment (S33b) may be performed under the same temperature and time conditions as the process of performing the first heat treatment (S31b) of the Embodiment 4.

FIG. 8 and FIG. 9 are views showing various embodiments for a case of performing a step of heat-treating an image sensor selected as having no defects in a method for reducing white spots of an image sensor.

Referring to FIG. 8 and FIG. 9, in the method for reducing the white spots of the image sensor of the embodiments, the heat treatment of the image sensor may be performed at 130 degrees Celsius or less for 10 hours to 30 hours.

In detail, referring to FIG. 8, in the method for reducing the white spots of the image sensor according to an Embodiment 6, the heat treatment of the image sensor may be performed for 10 hours to 14 hours or 11 hours to 13 hours in the range of 90 degrees Celsius to 150 degrees Celsius or 110 degrees Celsius to 130 degrees Celsius, for example.

Referring to FIG. 9, the method for reducing the white spots of the image sensor according to an Embodiment 7, the heat treatment of the image sensor may be performed for 22 hours to 26 hours or 23 hours to 25 hours in the range of 80 degrees Celsius to 140 degrees Celsius or 100 degrees Celsius to 120 degrees Celsius, for example.

The method for reducing the white spots of the image sensor according to another embodiment may include, in the manufacturing method of the image sensor: forming a color filter on a substrate; forming a microlens on the color filter; and heat-treating the image sensor in which the microlens is formed, and the heat treatment may be performed in multiple stages.

In the present embodiment, the manufacturing method of the image sensor is the same as the description referred to in FIG. 2 in an embodiment, so it is omitted here in the interest of brevity.

However, in the present embodiment, the forming of the microlens may be performed through patterning for a photosensitive layer and the heat treatment, and in this case, the heat treatment process may be performed in the various types described with reference to FIG. 3 to FIG. 9.

Hereinafter, an embodiment is described in detail. However, this is presented as an example, the present disclosure is not limited thereby, and the present disclosure is only defined by the range of appended claims.

Table 1 below shows results of measuring a ratio of additional defective chips after the heat treatment according to the Embodiment 1, Embodiment 2, Embodiment 4, Embodiment 5 and for a case (Reference 1) without the heat treatment for the image sensor after a certain period of time has elapsed after being screened out as having no defects, and Table 2 shows results of normalizing an occurrence rate of additional defective chips in Table 1 based on Reference 1.

TABLE 1

| | Number of | Number of | Additional |
|---|---|---|---|
| | additional | chips selected | defective |
| Division | defective chips | as good | rate |
| Embodiment 1 | 93 | 2464 | 3.8 |
| Embodiment 4 | 117 | 2404 | 4.9 |
| Embodiment 2 | 96 | 2402 | 4 |
| Embodiment 5 | 198 | 2231 | 8.9 |
| Reference 1 | 380 | 2397 | 15.9 |

TABLE 2

| Division | Additional defective rate |
|---|---|
| Embodiment 1 | 23.9 |
| Embodiment 4 | 30.8 |
| Embodiment 2 | 25.2 |
| Embodiment 5 | 56 |
| Reference 1 | 100 |

In Table 1 and Table 2, Reference 1 is a product that has passed about 7 months after being selected as an image sensor without defects.

Referring to Table 1 and Table 2, for Reference 1, even though the image sensor is tested after manufacturing the image sensor and is selected as having no defects, it may be confirmed that the additional defect rate is about 15.9% when tested again after a period of about 7 months has elapsed.

After being selected as a good product, the heat treatment process of multi-stages is performed as in Embodiment 1, Embodiment 2, Embodiment 4, and Embodiment 5 for the image sensor for which the period similar to Reference 1 had elapsed.

Specifically, Embodiment 1 is a case in which the second heat treatment is performed at 190 degrees Celsius for 2 hours after performing the first heat treatment at 120 degrees Celsius for 2 hours.

Embodiment 2 is a case in which the first heat treatment is performed at 120 degrees Celsius for 2 hours, the second heat treatment is performed at 190 degrees Celsius for 2 hours, and then the third heat treatment is performed at 120 degrees Celsius for 2 hours.

The Embodiment 4 is a case of performing the second heat treatment at 120 degrees Celsius for 2 hours after performing the first heat treatment at 190 degrees Celsius for 2 hours.

The Embodiment 5 is a case of performing the first heat treatment at 190 degrees Celsius for 2 hours, performing the second heat treatment at 120 degrees Celsius for 2 hours, and then performing the third heat treatment at 190 degrees Celsius for 2 hours.

It may be confirmed that Embodiment 1, Embodiment 2, Embodiment 4, and Embodiment 5 all have a significantly reduced rate of the additional defects compared to Reference 1. Particularly, in the case of Embodiments 1 and 2 in which the first heat treatment is performed at a relatively low temperature and then the second heat treatment is performed at a high temperature, it may be confirmed that the defect occurrence rate is reduced to a ¼ level.

Table 3 below shows results of measuring a ratio of additional defective chips after the heat treatment according to the Embodiment 3, Embodiment 6, and Embodiment 7 and for a case (Reference 2) without the heat treatment for the image sensor after a certain period of time has elapsed after being screened out as having no defects, and Table 4 is a result of normalizing an occurrence rate of additional defective chips in Table 3 based on Reference 2.

TABLE 3

| | Number of | Number of | Additional |
|---|---|---|---|
| | additional | chips selected | defective |
| Division | defective chips | as good | rate |
| Embodiment 3 | 243 | 2348 | 10.3 |
| Embodiment 6 | 318 | 2417 | 13.2 |
| Embodiment 7 | 323 | 2409 | 13.4 |
| Reference 2 | 593 | 2336 | 25.4 |

TABLE 4

| Division | Additional defective rate |
|---|---|
| Embodiment 3 | 40.8 |
| Embodiment 6 | 51.8 |
| Embodiment 7 | 56.8 |
| Reference 2 | 100 |

In Table 3 and Table 4, Reference 2 is a product that has passed about 8 months after being selected as an image sensor without defects.

Referring to Table 3 and Table 4, for Reference 2, even though the image sensor is tested after manufacturing the image sensor and is selected as having no defects, it may be confirmed that the additional defect rate is about 25.4% when tested again after a period of about 8 months has elapsed.

After being selected as a good product, the heat treatment process is performed as in Embodiment 3, Embodiment 6, and Embodiment 7 for the image sensor for which a period similar to Reference 2 had elapsed.

Specifically, Embodiment 3 is a case in which the second heat treatment is performed at 150 degrees Celsius for 2 hours after performing the first heat treatment at 120 degrees Celsius for 2 hours.

Embodiment 6 is a case in which the heat treatment is performed at 120 degrees Celsius for 12 hours.

Embodiment 7 is a case of performing the heat treatment at 110 degrees Celsius for 24 hours.

It may be confirmed Embodiment 3, Embodiment 6, and Embodiment 7 all reduced the additional defect occurrence rate compared to reference 2 by nearly 50%.

Therefore, it may be confirmed that the occurrence rate of the defects may be reduced by performing the heat treatment for a long time at a relatively low temperature for the image sensor selected as a good product.

Also, referring to Embodiment 3 and Embodiments 6 and 7, even when heat treatment is performed, it may be confirmed that the defect occurrence rate of Embodiment 3, which is subjected to the heat treatment in multiple steps for a short time, is further reduced compared to Embodiments 6 and 7, for which the heat treatment is performed at low temperature for a long time.

While the present disclosure has been described in connection with what is presently considered to be practical embodiments, it is to be understood that the disclosure is not limited to the disclosed embodiments. On the contrary, it is intended to cover various modifications and equivalent arrangements included within the spirit and scope of the appended claims.

What is claimed is:

1. A method for reducing white spots of an image sensor, comprising:
manufacturing an image sensor;
testing the manufactured image sensor to select an image sensor without defects; and
heat-treating the selected image sensor without defects.

2. The method for reducing white spots of the image sensor of claim 1, wherein
the heat-treating is performed in multiple stages.

3. The method for reducing white spots of the image sensor of claim 2, wherein
the heat-treating performed in multiple stages includes
a first heat treatment performed at 150 degrees Celsius or less, and
a second heat treatment performed at a higher temperature than the first heat treatment.

4. The method for reducing white spots of the image sensor of claim 3, wherein
a temperature difference between the first heat treatment and the second heat treatment is more than 50 degrees Celsius.

5. The method for reducing white spots of the image sensor of claim 3, wherein
the first heat treatment is performed in a range of 70 degrees Celsius to 120 degrees Celsius for 30 minutes to 5 hours.

6. The method for reducing white spots of the image sensor of claim 3, wherein
the heat-treating performed in multiple stages further includes a third heat treatment performed at a lower temperature than the second heat treatment after the second heat treatment.

7. The method for reducing white spots of the image sensor of claim 6, wherein
the third heat treatment is performed under the same temperature and time conditions as the first heat treatment.

8. The method for reducing white spots of the image sensor of claim 3, wherein
a temperature difference between the first heat treatment and the second heat treatment is less than 50 degrees Celsius.

9. The method for reducing white spots of the image sensor of claim 2, wherein
the heat-treating performed in multiple stages includes
a first heat treatment is performed at 170 degrees Celsius or higher, and
a second heat treatment is performed at a lower temperature than the first heat treatment.

10. The method for reducing white spots of the image sensor of claim 9, wherein
the first heat treatment is performed in a range of 170 degrees Celsius to 220 degrees Celsius for 30 minutes to 5 hours.

11. The method for reducing white spots of the image sensor of claim 9, wherein
the heat-treating performed in multiple stages further includes a third heat treatment performed at a higher temperature than the second heat treatment after the second heat treatment.

12. The method for reducing white spots of the image sensor of claim 11, wherein
the third heat treatment is performed at the same temperature as the first heat treatment.

13. The method for reducing white spots of the image sensor of claim 1, wherein
heat-treating step is performed at 130° C. or lower for 10 to 30 hours.

14. A method for reducing white spots of an image sensor, comprising:
manufacturing an image sensor;
testing the manufactured image sensor to select an image sensor without defects;
first heat-treating the selected image sensor without defects in a range of 70 degrees Celsius to 120 degrees Celsius for 30 minutes to 5 hours; and
second heat-treating the first heat-treated image sensor at a temperature at least 50 degrees Celsius higher than that of the first heat-treating.

15. The method for reducing white spots of the image sensor of claim 14, further comprising
third heat-treating the second heat-treated image sensor under the same temperature and time conditions as the first heat-treating.

16. A method for reducing white spots of an image sensor, comprising:
in a manufacturing method of an image sensor,
forming a color filter on a substrate;
forming a microlens on the color filter; and
heat-treating the image sensor on which the microlens is formed,
wherein the heat-treating is performed in multiple stages.

17. The method for reducing white spots of the image sensor of claim 16, wherein
the heat-treating performed in multiple stages includes
a first heat treatment performed at 150 degrees Celsius or less, and
a second heat treatment performed at a higher temperature than the first heat treatment,
and a temperature difference between the first heat treatment and the second heat treatment is more than 50 degrees Celsius.

18. The method for reducing white spots of the image sensor of claim 17, further comprising
a third heat treatment performed at the same temperature and time conditions as the first heat treatment after the second heat treatment.

19. The method for reducing white spots of the image sensor of claim 16, wherein
the heat-treating performed in multiple stages includes
a first heat treatment performed at 170 degrees Celsius or higher, and
a second heat treatment performed at a lower temperature than the first heat treatment.

20. The method for reducing white spots of the image sensor of claim 19, further comprising
a third heat treatment performed at the same temperature and time conditions as the first heat treatment after the second heat treatment.
